(19) United States
(12) Patent Application Publication
(10) Pub. No.: US 2024/0043999 A1
(43) Pub. Date: Feb. 8, 2024

(54) SINGLE PROCESS GAS FEED LINE ARCHITECTURE

(71) Applicant: Applied Materials, Inc., Santa Clara, CA (US)

(72) Inventors: Abhijit A. Kangude, San Jose, CA (US); Arun Chakravarthy Chakravarthy, Panruit (IN)

(73) Assignee: Applied Materials, Inc., Santa Clara, CA (US)

(21) Appl. No.: 17/880,310

(22) Filed: Aug. 3, 2022

(51) Int. Cl. C23C 16/455; C23C 16/24

(52) U.S. Cl. CPC C23C 16/45561; C23C 16/24; C23C 16/45512

(57) ABSTRACT

Exemplary semiconductor processing systems may a lid plate. A gas splitter may be seated on the lid plate. The gas splitter may include a top surface and a plurality of side surfaces. The gas splitter may defines a gas inlet, one or more gas outlets, and one or more gas lumens. The one or more gas lumens may extend between and fluidly couple the gas inlet with each of the one or more gas outlets. A primary gas weldment may extend to and fluidly couples to the gas inlet. A gas panel may include a first fluid source and a second fluid source that are each fluidly coupled with the primary gas weldment. One or more secondary gas weldments may extend between and fluidly couple each of the one or more gas outlets with a respective one of the plurality of processing chambers.

### TECHNICAL FIELD

The present technology relates to semiconductor processes and equipment. More specifically, the present technology relates to semiconductor processing systems and components.

### BACKGROUND

Semiconductor processing systems often utilize cluster tools to integrate a number of process chambers together. This configuration may facilitate the performance of several sequential processing operations without removing the substrate from a controlled processing environment, or it may allow a similar process to be performed on multiple substrates at once in the varying chambers. These chambers may include, for example, degas chambers, pretreatment chambers, transfer chambers, chemical vapor deposition chambers, physical vapor deposition chambers, etch chambers, metrology chambers, and other chambers. The combination of chambers in a cluster tool, as well as the operating conditions and parameters under which these chambers are run, are selected to fabricate specific structures using particular process recipes and process flows.

Oftentimes, processing systems include gas distribution systems that may mix and/or otherwise deliver a number of process gases to the various chambers. The temperature and flow of these gases may need to be carefully controlled in attempt to achieve a desired deposition rate ensure uniform flow of gases into each of the processing chambers.

Thus, there is a need for improved systems and methods that can be used to efficiently mix and/or otherwise deliver gases to processing chambers under desired conditions. These and other needs are addressed by the present technology.

### SUMMARY

Exemplary semiconductor processing systems may include a plurality of processing chambers. Each processing chamber may define a processing region. The semiconductor processing systems may include a lid plate positioned above the plurality of processing chambers. The semiconductor processing systems may include a gas splitter seated on the lid plate. The gas splitter may include a top surface and a plurality of side surfaces. The gas splitter may define a single gas inlet, one or more gas outlets, and one or more gas lumens. The one or more gas lumens may extend between and fluidly couple the gas inlet with each of the one or more gas outlets. A primary gas weldment may extend to and fluidly couple to the gas inlet. The primary gas weldment may deliver a mixture of process gases to the plurality of processing chambers. At least one gas mixing valve may include a first valve inlet, a second valve inlet, and a valve outlet. The valve outlet may be coupled with an inlet end of the primary gas weldment. One or more secondary gas weldments may extend between and fluidly couple each of the one or more gas outlets with a respective one of the plurality of processing chambers.

In some embodiments, the systems may include a gas panel comprising a first gas source fluidly coupled with the first valve inlet and a second gas source fluidly coupled with the second valve inlet. The systems may include a gas heater disposed upstream of the at least one mixing valve. The gas heater may be operable to preheat at least one of the mixture of process gases. The systems may include a divert weldment in fluid communication with the primary gas weldment proximate a gas panel. The systems may include one or more orifices disposed between the one or more gas outlets and the plurality of processing chambers. The one or more orifices may have an internal diameter less than an internal diameter relative to fluid lines disposed upstream and downstream of each of the one or more orifices. The systems may include between one and six heater jackets surrounding the primary gas weldment. The systems may include a plurality of output manifolds seated on the lid plate. Each of the one or more secondary gas weldments may be fluidly coupled with a respective one of the plurality of output manifolds.

Some embodiments of the present technology may encompass semiconductor processing systems that may include a lid plate. The systems may include a gas splitter seated on the lid plate. The gas splitter may include a top surface and a plurality of side surfaces. The gas splitter may define a gas inlet. The gas splitter may define one or more gas outlets. The gas splitter may define one or more gas lumens that extend between and fluidly couple the gas inlet with each of the one or more gas outlets. The systems may include a primary gas weldment that extends to and fluidly couples to the gas inlet. The primary gas weldment may deliver a mixture of process gases to a plurality of processing chambers. The systems may include a gas panel that includes a first fluid source and a second fluid source that are each fluidly coupled with the primary gas weldment. The systems may include one or more secondary gas weldments extending between and fluidly coupling each of the one or more gas outlets with a respective one of the plurality of processing chambers.

In some embodiments, the systems may include a gas heater in fluid communication with the primary gas weldment. The gas heater may be operable to preheat at least one of the mixture of process gases. The systems may include a divert weldment in fluid communication with the primary gas weldment proximate the gas panel. The systems may include one or more orifices between the one or more gas outlets and the plurality of processing chambers. The one or more orifices may have an internal diameter less than an internal diameter relative to fluid lines disposed upstream and downstream of each of the one or more orifices. The one or more orifices may be removable such that inner diameters of the one or more orifices may be modified. Each of the one or more orifices may have an internal diameter of between about 1.70 mm and about 2.40 mm. The systems may include between one and six heater jackets surrounding the primary gas weldment. The systems may include at least one gas mixing valve having a first valve inlet, a second valve inlet, and a valve outlet. The first valve inlet may be in fluid communication with a gas heater, the gas heater operable to heat gas prior to being passed to the first valve inlet. The valve outlet may be coupled with an inlet end of the primary gas weldment.

Some embodiments of the present invention may encompass semiconductor processing methods. The methods may include introducing a mixture of process gases into a primary gas weldment. The mixture of process gases may include at least two process gases. The methods may include flowing the mixture of process gases into a gas splitter via a gas inlet. The methods may include splitting a flow of the mixture of process gases into a plurality of gas lumens defined by the gas splitter. The methods may include flowing portions of the mixture of process gases into respective processing chambers via a plurality of secondary gas weldments coupled with gas outlet ends of each of the plurality of gas lumens.

In some embodiments, the methods may include heating at least one of the mixture of process gases prior to introducing the mixture of process gases into the primary gas weldment. The methods may include directing a divert portion of the mixture of process gases into a divert weldment. The methods may include flowing the divert portion of the mixture of process gases through the divert weldment and into a divert foreline. The methods may include combining at least a first process gas and a second process gas to form the mixture of process gases. The first process gas may include O₂ and the second process gas comprises TEOS. The methods may include heating the Oₑ prior to combining the O₂ and the TEOS.

Such technology may provide numerous benefits over conventional systems and techniques. For example, the processing systems may provide multi-substrate processing capabilities that may be scaled well beyond conventional designs. Additionally, the processing systems may provide equal flow splitting between multiple chambers, while preventing cross-talk between the chambers. The processing systems may use passive flow control devices to tune flow to multiple chambers, and may reduce power consumption. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic top plan view of an exemplary processing system according to some embodiments of the present technology.

FIG. 2 shows a schematic isometric view of a transfer region of an exemplary chamber system according to some embodiments of the present technology.

FIG. 3 shows a schematic isometric view of a transfer region of an exemplary chamber system according to some embodiments of the present technology.

FIG. 4 shows a schematic isometric view of a transfer region of an exemplary chamber system according to some embodiments of the present technology.

FIG. 5 shows a schematic partial isometric view of a chamber system according to some embodiments of the present technology.

FIG. 6 shows a schematic isometric view of an exemplary processing system according to some embodiments of the present technology.

FIG. 7 shows a schematic cross-sectional top plan view of an exemplary gas splitter according to some embodiments of the present technology.

FIG. 8A shows a partial schematic isometric view of a choke plate coupled with the gas splitter of FIG. 7 according to some embodiments of the present technology.

FIG. 8B shows a partial schematic top plan view of the choke plate coupled with the gas splitter of FIG. 7 according to some embodiments of the present technology.

FIG. 9 shows a partial schematic isometric view of gas panel according to some embodiments of the present technology.

FIG. 10 shows operations of an exemplary semiconductor processing method according to some embodiments of the present technology.

Several of the figures are included as schematics. It is to be understood that the figures are for illustrative purposes, and are not to be considered of scale or proportion unless specifically stated to be of scale or proportion. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Substrate processing can include time-intensive operations for adding, removing, or otherwise modifying materials on a wafer or semiconductor substrate. Efficient movement of the substrate may reduce queue times and improve substrate throughput. To improve the number of substrates processed within a cluster tool, additional chambers may be incorporated onto the mainframe. Although transfer robots and processing chambers can be continually added by lengthening the tool, this may become space inefficient as the footprint of the cluster tool scales. Accordingly, the present technology may include cluster tools with an increased number of processing chambers within a defined footprint. To accommodate the limited footprint about transfer robots, the present technology may increase the number of processing chambers laterally outward from the robot. For example, some conventional cluster tools may include one or two processing chambers positioned about sections of a centrally located transfer robot to maximize the number of chambers radially about the robot. The present technology may expand on this concept by incorporating additional chambers laterally outward as another row or group of chambers. For example, the present technology may be applied with cluster tools including three, four, five, six, or more processing chambers accessible at each of one or more robot access positions.

However, as additional process locations are added, process rates, such as deposition or etch rates, may decrease as the rate of the reagents and/or precursors being provided to the processing system may be split amongst additional processing chambers. To ensure that gas flow to each of the chambers is uniform, conventional chambers may utilize gas splitters that include valves, mass flow controllers, and/or other active flow control devices to adjust the flow of gas to each chamber. However, these active flow control devices may introduce other complexities into the processing system. For example, timing differences between the actuation of different active flow control devices may introduce non-uniformity between the various chambers. Additionally, the active flow control devices, along with heating elements, may require large amounts of power to operate the processing system.

The present technology may overcome these issues by providing a single process gas line to the gas splitter. For example, embodiments, may include one or more valves that mix a number of process gases from the gas panel prior to reaching the gas splitter. Additionally, by delivering the process gases to the gas splitter via a single gas line, the processing systems may utilize passive flow control devices to carefully tune the gas flow to each processing chamber. The passive flow control devices may be used to reduce any mismatch between flow rates/volume between the processing chambers without the use of active flow control devices. By eliminating the need for valves and other active flow control devices, embodiments may reduce the power consumption of the processing system and may also eliminate problems associated with such devices, such as pressure spikes and timing mismatches. The processing systems may include a heater that actively heats one or more of the process gases to provide greater temperature control, as well as reducing the amount of heating elements in the system. The heater may be positioned adjacent to or near an outlet of the gas panel. This may, in turn, reduce the power consumption of the processing systems.

Although the remaining disclosure will routinely identify specific structures, such as four-position chamber systems, for which the present structures and methods may be employed, it will be readily understood that the systems and methods are equally applicable to any number of structures and devices that may benefit from the structural capabilities explained. Accordingly, the technology should not be considered to be so limited as for use with any particular structures alone. Moreover, although an exemplary tool system will be described to provide foundation for the present technology, it is to be understood that the present technology can be incorporated with any number of semiconductor processing chambers and tools that may benefit from some or all of the operations and systems to be described.

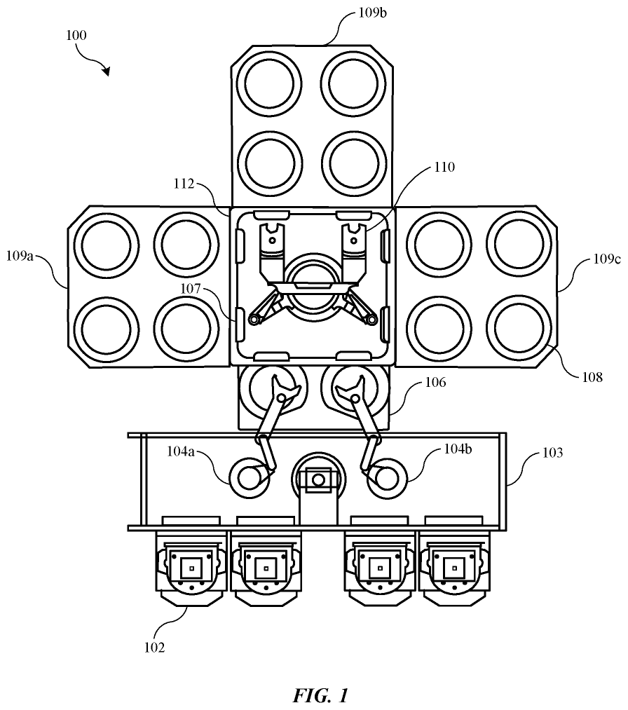

FIG. 1 shows a top plan view of one embodiment of a substrate processing tool or processing system 100 of deposition, etching, baking, and curing chambers according to some embodiments of the present technology. In the figure, a set of front-opening unified pods 102 supply substrates of a variety of sizes that are received within a factory interface 103 by robotic arms 104a and 104b and placed into a load lock or low pressure holding area 106 before being delivered to one of the semiconductor processing regions 108, positioned in chamber systems or quad sections 109a-c, which may each be a substrate processing system having a transfer region fluidly coupled with a plurality of processing regions 108. Although a quad system is illustrated, it is to be understood that platforms incorporating standalone chambers, twin chambers, and other multiple chamber systems are equally encompassed by the present technology. A second robotic arm 110 housed in a transfer chamber 112 may be used to transport the substrate wafers from the holding area 106 to the quad sections 109 and back, and second robotic arm 110 may be housed in a transfer chamber with which each of the quad sections or processing systems may be connected. Each semiconductor processing region 108 can be outfitted to perform a number of substrate processing operations including any number of deposition processes including cyclical layer deposition, atomic layer deposition, chemical vapor deposition, physical vapor deposition, as well as etch, pre-clean, anneal, plasma processing, degas, orientation, and other substrate processes.

Each quad section 109 may include a transfer region that may receive substrates from, and deliver substrates to, second robotic arm 110. The transfer region of the chamber system may be aligned with the transfer chamber having the second robotic arm 110. In some embodiments the transfer region may be laterally accessible to the robot. In subsequent operations, components of the transfer sections may vertically translate the substrates into the overlying processing regions 108. Similarly, the transfer regions may also be operable to rotate substrates between positions within each transfer region. The semiconductor processing regions 108 may include any number of system components for depositing, annealing, curing and/or etching a material film on the substrate or wafer. In one configuration, two sets of the processing regions, such as the processing regions in quad section 109a and 109b, may be used to deposit material on the substrate, and the third set of processing chambers, such as the processing chambers or regions in quad section 109c, may be used to cure, anneal, or treat the deposited films. In another configuration, all three sets of chambers, such as all twelve chambers illustrated, may be configured to both deposit and/or cure a film on the substrate.

As illustrated in the figure, second robotic arm 110 may include two arms for delivering and/or retrieving multiple substrates simultaneously. For example, each quad section 109 may include two accesses 107 along a surface of a housing of the transfer region, which may be laterally aligned with the second robotic arm. The accesses may be defined along a surface adjacent the transfer chamber 112. In some embodiments, such as illustrated, the first access may be aligned with a first substrate support of the plurality of substrate supports of a quad section. Additionally, the second access may be aligned with a second substrate support of the plurality of substrate supports of the quad section. The first substrate support may be adjacent to the second substrate support, and the two substrate supports may define a first row of substrate supports in some embodiments. As shown in the illustrated configuration, a second row of substrate supports may be positioned behind the first row of substrate supports laterally outward from the transfer chamber 112. The two arms of the second robotic arm 110 may be spaced to allow the two arms to simultaneously enter a quad section or chamber system to deliver or retrieve one or two substrates to substrate supports within the transfer region.

Any one or more of the transfer regions described may be incorporated with additional chambers separated from the fabrication system shown in different embodiments. It will be appreciated that additional configurations of deposition, etching, annealing, and curing chambers for material films are contemplated by processing system 100. Additionally, any number of other processing systems may be utilized with the present technology, which may incorporate transfer systems for performing any of the specific operations, such as the substrate movement. In some embodiments, processing systems that may provide access to multiple processing chamber regions while maintaining a vacuum environment in various sections, such as the noted holding and transfer areas, may allow operations to be performed in multiple chambers while maintaining a particular vacuum environment between discrete processes.

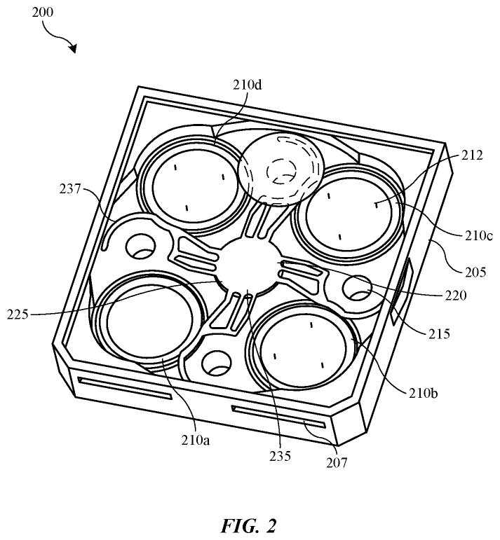

As noted, processing system 100, or more specifically quad sections or chamber systems incorporated with processing system 100 or other processing systems, may include transfer sections positioned below the processing chamber regions illustrated. FIG. 2 shows a schematic isometric view of a transfer section of an exemplary chamber system 200 according to some embodiments of the present technology. FIG. 2 may illustrate additional aspects or variations of aspects of the transfer region described above, and may include any of the components or characteristics described. The system illustrated may include a transfer region housing 205, which may be a chamber body as discussed further below, defining a transfer region in which a number of components may be included. The transfer region may additionally be at least partially defined from above by processing chambers or processing regions fluidly coupled with the transfer region, such as processing chamber regions 108 illustrated in quad sections 109 of FIG. 1. A sidewall of the transfer region housing may define one or more access locations 207 through which substrates may be delivered and retrieved, such as by second robotic arm 110 as discussed above. Access locations 207 may be slit valves or other sealable access positions, which include doors or other sealing mechanisms to provide a hermetic environment within transfer region housing 205 in some embodiments. Although illustrated with two such access locations 207, it is to be understood that in some embodiments only a single access location 207 may be included, as well as access locations on multiple sides of the transfer region housing. It is also to be understood that the transfer section illustrated may be sized to accommodate any substrate size, including 200 mm, 300 mm, 450 mm, or larger or smaller substrates, including substrates characterized by any number of geometries or shapes.

Within transfer region housing 205 may be a plurality of substrate supports 210 positioned about the transfer region volume. Although four substrate supports are illustrated, it is to be understood that any number of substrate supports are similarly encompassed by embodiments of the present technology. For example, greater than or about three, four, five, six, eight, or more substrate supports 210 may be accommodated in transfer regions according to embodiments of the present technology. Second robotic arm 110 may deliver a substrate to either or both of substrate supports 210a or 210b through the access locations 207. Similarly, second robotic arm 110 may retrieve substrates from these locations. Lift pins 212 may protrude from the substrate supports 210, and may allow the robot to access beneath the substrates. The lift pins may be fixed on the substrate supports, or at a location where the substrate supports may recess below, or the lift pins may additionally be raised or lowered through the substrate supports in some embodiments. Substrate supports 210 may be vertically translatable, and in some embodiments may extend up to processing chamber regions of the semiconductor processing systems, such as processing chamber regions 108, positioned above the transfer region housing 205.

The transfer region housing 205 may provide access 215 for alignment systems, which may include an aligner that can extend through an aperture of the transfer region housing as illustrated and may operate in conjunction with a laser, camera, or other monitoring device protruding or transmitting through an adjacent aperture, and that may determine whether a substrate being translated is properly aligned. Transfer region housing 205 may also include a transfer apparatus 220 that may be operated in a number of ways to position substrates and move substrates between the various substrate supports. In one example, transfer apparatus 220 may move substrates on substrate supports 210a and 210b to substrate supports 210c and 210d, which may allow additional substrates to be delivered into the transfer chamber. Additional transfer operations may include rotating substrates between substrate supports for additional processing in overlying processing regions.

Transfer apparatus 220 may include a central hub 225 that may include one or more shafts extending into the transfer chamber. Coupled with the shaft may be an end effector 235. End effector 235 may include a plurality of arms 237 extending radially or laterally outward from the central hub. Although illustrated with a central body from which the arms extend, the end effector may additionally include separate arms that are each coupled with the shaft or central hub in various embodiments. Any number of arms may be included in embodiments of the present technology. In some embodiments a number of arms 237 may be similar or equal to the number of substrate supports 210 included in the chamber. Hence, as illustrated, for four substrate supports, transfer apparatus 220 may include four arms extending from the end effector. The arms may be characterized by any number of shapes and profiles, such as straight profiles or arcuate profiles, as well as including any number of distal profiles including hooks, rings, forks, or other designs for supporting a substrate and/or providing access to a substrate, such as for alignment or engagement.

The end effector 235, or components or portions of the end effector, may be used to contact substrates during transfer or movement. These components as well as the end effector may be made from or include a number of materials including conductive and/or insulative materials. The materials may be coated or plated in some embodiments to withstand contact with precursors or other chemicals that may pass into the transfer chamber from an overlying processing chamber.

Additionally, the materials may be provided or selected to withstand other environmental characteristics, such as temperature. In some embodiments, the substrate supports may be operable to heat a substrate disposed on the support. The substrate supports may be configured to increase a surface or substrate temperature to temperatures greater than or about 100° C., greater than or about 200° C., greater than or about 300° C., greater than or about 400° C., greater than or about 500° C., greater than or about 600° C., greater than or about 700° C., greater than or about 800° C., or higher. Any of these temperatures may be maintained during operations, and thus components of the transfer apparatus 220 may be exposed to any of these stated or encompassed temperatures. Consequently, in some embodiments any of the materials may be selected to accommodate these temperature regimes, and may include materials such as ceramics and metals that may be characterized by relatively low coefficients of thermal expansion, or other beneficial characteristics.

Component couplings may also be adapted for operation in high temperature and/or corrosive environments. For example, where end effectors and end portions are each ceramic, the coupling may include press fittings, snap fittings, or other fittings that may not include additional materials, such as bolts, which may expand and contract with temperature, and may cause cracking in the ceramics. In some embodiments the end portions may be continuous with the end effectors, and may be monolithically formed with the end effectors. Any number of other materials may be utilized that may facilitate operation or resistance during operation, and are similarly encompassed by the present technology. The transfer apparatus 220 may include a number of components and configurations that may facilitate the movement of the end effector in multiple directions, which may facilitate rotational movement, as well as vertical movement, or lateral movement in one or more ways with the drive system components to which the end effector may be coupled.

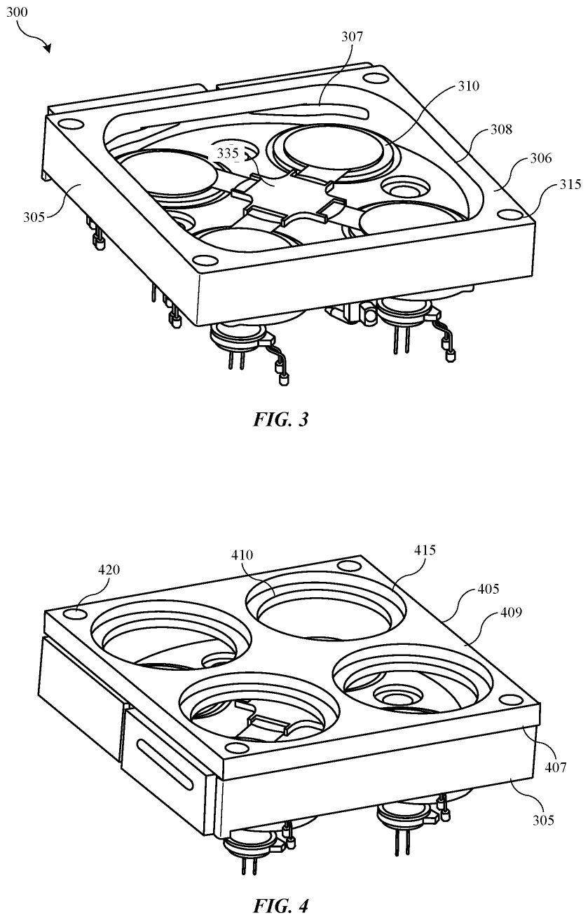

FIG. 3 shows a schematic isometric view of a transfer region of a chamber system 300 of an exemplary chamber system according to some embodiments of the present technology. Chamber system 300 may be similar to the transfer region of chamber system 200 described above, and may include similar components including any of the components, characteristics, or configurations described above. FIG. 3 may also illustrate certain component couplings encompassed by the present technology along with the following figures.

Chamber system 300 may include a chamber body 305 or housing defining the transfer region. Within the defined volume may be a plurality of substrate supports 310 distributed about the chamber body as previously described. As will be described further below, each substrate support 310 may be vertically translatable along a central axis of the substrate support between a first position illustrated in the figure, and a second position where substrate processing may be performed. Chamber body 305 may also define one or more accesses 307 through the chamber body. A transfer apparatus 335 may be positioned within the transfer region and be configured to engage and rotate substrates among the substrate supports 310 within the transfer region as previously described. For example, transfer apparatus 335 may be rotatable about a central axis of the transfer apparatus to reposition substrates. The transfer apparatus 335 may also be laterally translatable in some embodiments to further facilitate repositioning substrates at each substrate support.

Chamber body 305 may include a top surface 306, which may provide support for overlying components of the system. Top surface 306 may define a gasket groove 308, which may provide seating for a gasket to provide hermetic sealing of overlying components for vacuum processing. Unlike some conventional systems, chamber system 300, and other chamber systems according to some embodiments of the present technology, may include an open transfer region within the processing chamber, and processing regions may be formed overlying the transfer region. Because of transfer apparatus 335 creating an area of sweep, supports or structure for separating processing regions may not be available. Consequently, the present technology may utilize overlying lid structures to form segregated processing regions overlying the open transfer region as will be described below. Hence, in some embodiments sealing between the chamber body and an overlying component may only occur about an outer chamber body wall defining the transfer region, and interior coupling may not be present in some embodiments. Chamber body 305 may also define apertures 315, which may facilitate exhaust flow from the processing regions of the overlying structures. Top surface 306 of chamber body 305 may also define one or more gasket grooves about the apertures 315 for sealing with an overlying component. Additionally, the apertures may provide locating features that may facilitate stacking of components in some embodiments.

FIG. 4 shows a schematic isometric view of overlying structures of chamber system 300 according to some embodiments of the present technology. For example, in some embodiments a first lid plate 405 may be seated on chamber body 305. First lid plate 405 may by characterized by a first surface 407 and a second surface 409 opposite the first surface. First surface 407 of the first lid plate 405 may contact chamber body 305, and may define companion grooves to cooperate with grooves 308 discussed above to produce a gasket channel between the components. First lid plate 405 may also define apertures 410, which may provide separation of overlying regions of the transfer chamber to form processing regions for substrate processing.

Apertures 410 may be defined through first lid plate 405, and may be at least partially aligned with substrate supports in the transfer region. In some embodiments, a number of apertures 410 may equal a number of substrate supports in the transfer region, and each aperture 410 may be axially aligned with a substrate support of the plurality of substrate supports. As will be described further below, the processing regions may be at least partially defined by the substrate supports when vertically raised to a second position within the chamber systems. The substrate supports may extend through the apertures 410 of the first lid plate 405. Accordingly, in some embodiments, apertures 410 of the first lid plate 405 may be characterized by a diameter greater than a diameter of an associated substrate support. Depending on an amount of clearance, the diameter may be less than or about 25% greater than a diameter of a substrate support, and in some embodiments may be less than or about 20% greater, less than or about 15% greater, less than or about 10% greater, less than or about 9% greater, less than or about 8% greater, less than or about 7% greater, less than or about 6% greater, less than or about 5% greater, less than or about 4% greater, less than or about 3% greater, less than or about 2% greater, less than or about 1% greater than a diameter of a substrate support, or less, which may provide a minimum gap distance between the substrate support and the apertures 410.

First lid plate 405 may also include a second surface 409 opposite first surface 407. Second surface 409 may define a recessed ledge 415, which may produce an annular recessed shelf through the second surface 409 of first lid plate 405. Recessed ledges 415 may be defined about each aperture of the plurality of apertures 410 in some embodiments. The recessed shelf may provide support for lid stack components as will be described further below. Additionally, first lid plate 405 may define second apertures 420, which may at least partially define pumping channels from overlying components described below. Second apertures 420 may be axially aligned with apertures 315 of the chamber body 305 described previously.

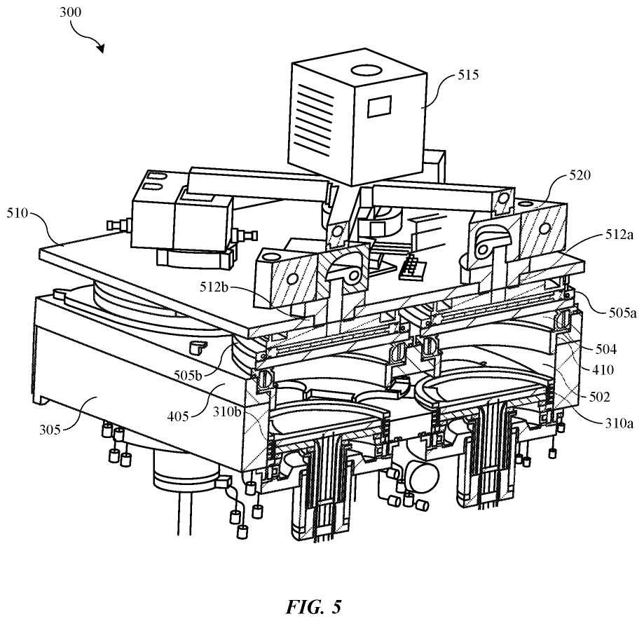

FIG. 5 shows a schematic partial isometric view of chamber system 300 according to some embodiments of the present technology. The figure may illustrate a partial cross-section through two processing regions and a portion of a transfer region of the chamber system. For example, chamber system 300 may be a quad section of processing system 100 described previously, and may include any of the components of any of the previously described components or systems.

Chamber system 300, as developed through the figure, may include a chamber body 305 defining a transfer region 502 including substrate supports 310, which may extend into the chamber body 305 and be vertically translatable as previously described. First lid plate 405 may be seated overlying the chamber body 305, and may define apertures 410 producing access for processing region 504 to be formed with additional chamber system components. Seated about or at least partially within each aperture may be a lid stack 505, and chamber system 300 may include a plurality of lid stacks 505, including a number of lid stacks equal to a number of apertures 410 of the plurality of apertures. Each lid stack 505 may be seated on the first lid plate 405, and may be seated on a shelf produced by recessed ledges through the second surface of the first lid plate. The lid stacks 505 may at least partially define processing regions 504 of the chamber system 300.

As illustrated, processing regions 504 may be vertically offset from the transfer region 502, but may be fluidly coupled with the transfer region. Additionally, the processing regions may be separated from the other processing regions. Although the processing regions may be fluidly coupled with other processing regions through the transfer region from below, the processing regions may be fluidly isolated, from above, from each of the other processing regions. Each lid stack 505 may also be aligned with a substrate support in some embodiments. For example, as illustrated, lid stack 505a may be aligned over substrate support 310a, and lid stack 505b may be aligned over substrate support 310b. When raised to operational positions, such as a second position, the substrates may deliver substrates for individual processing within the separate processing regions. When in this position, as will be described further below, each processing region 504 may be at least partially defined from below by an associated substrate support in the second position.

FIG. 5 also illustrates embodiments in which a second lid plate 510 may be included for the chamber system. Second lid plate 510 may be coupled with each of the lid stacks, which may be positioned between the first lid plate 405 and the second lid plate 510 in some embodiments. As will be explained below, the second lid plate 510 may facilitate accessing components of the lid stacks 505. Second lid plate 510 may define a plurality of apertures 512 through the second lid plate. Each aperture of the plurality of apertures may be defined to provide fluid access to a specific lid stack 505 or processing region 504. A remote plasma unit 515 may optionally be included in chamber system 300 in some embodiments, and may be supported on second lid plate 510. In some embodiments, remote plasma unit 515 may be fluidly coupled with each aperture 512 of the plurality of apertures through second lid plate 510. Isolation valves 520 may be included along each fluid line to provide fluid control to each individual processing region 504. For example, as illustrated, aperture 512a may provide fluid access to lid stack 505a. Aperture 512a may also be axially aligned with any of the lid stack components, as well as with substrate support 310a in some embodiments, which may produce an axial alignment for each of the components associated with individual processing regions, such as along a central axis through the substrate support or any of the components associated with a particular processing region 504. Similarly, aperture 512b may provide fluid access to lid stack 505b, and may be aligned, including axially aligned with components of the lid stack as well as substrate support 310b in some embodiments.

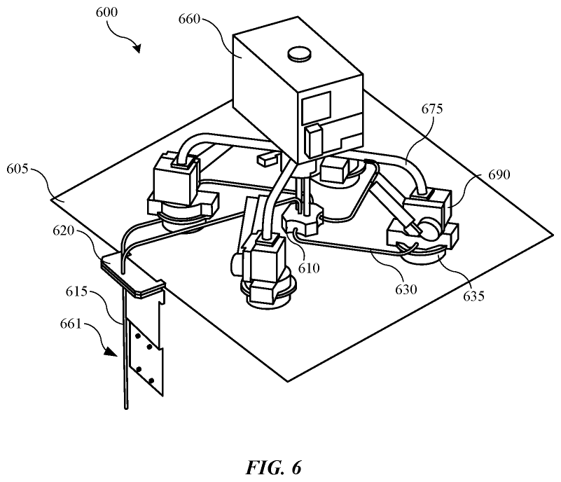

FIG. 6 shows a schematic isometric plan view of one embodiment of a semiconductor processing system 600 according to some embodiments of the present technology. The figure may include components of any of the systems illustrated and described previously, and may also show further aspects of any of the previously described systems. It is to be understood that the illustration may also show exemplary components as would be seen on any quad section 109 described above.

Semiconductor processing system 600 may include a lid plate 605, which may be similar to second lid plate 510 previously described. For example, the lid plate 605 may define a number of apertures, similar to apertures 512, which provide access to a number of processing chambers positioned beneath the lid plate 605. Each aperture of the plurality of apertures may be defined to provide fluid access to a specific lid stack, processing chamber, and/or processing region.

A gas splitter 610 may be seated on a top surface of the lid plate 605. For example, the gas splitter 610 may be centered between the apertures of the lid plate 605. In some embodiments, one or more polymer and/or other insulative spacers, such as PEEK spacers, may be provided between a bottom surface of the gas splitter 610 and the lid plate 605. The spacers may help reduce heat transfer between the gas splitter 610 and the lid plate 605, which may help improve process conditions and/or reduce power consumption of system 600 (such as by reducing the amount of power needed to heat the gas splitter 610). The gas splitter 610 may be fluidly coupled with a primary gas weldment 615 that delivers one or more process gases, such as precursors, plasma effluents, and/or purge gases from a number of gas sources to the gas splitter 610. For example, the primary gas weldment 615 may extend vertically from gas sources, such as a gas panel, positioned below the lid plate 605 and pass through a feedthrough plate 620. A portion of the primary gas weldment 615 above the feedthrough plate 620 may be bent horizontally and may direct the gases toward the gas splitter 610. In some embodiments, the primary gas weldment 615 may be disposed within one or more heater jackets 661 that help prevent heat loss along the length of the primary gas weldment 615.

As will be discussed further below, the gas splitter 610 may receive gases from the primary gas weldment 615 and may split the gas flows into a greater number of gas outputs that are each interfaced with a respective one of a number of secondary weldments 630. Each secondary weldment 630 may deliver the purge gas and/or process gas to an output manifold 635 associated with a particular processing chamber. For example, an output manifold 635 may be positioned over each aperture formed within the lid plate 605 and may be fluidly coupled with the lid stack components to deliver one or more gases to a processing region of a respective processing chamber.

A remote plasma unit 660 may be supported atop the lid plate 605 and may be fluidly coupled with each of the output manifolds 635. For example, each output manifold 635 may define a central aperture that may be fluidly coupled with the remote plasma unit 660 using a manifold assembly. The remote plasma unit 660 may be positioned above each of the output manifolds 635. The remote plasma unit 660 may provide precursors, plasma effluents, cleaning gases, and/or purge gas to the output manifolds 635 for subsequent delivery to the processing chambers for film deposition, chamber cleaning, and/or other processing operations. The manifold assembly may include a central manifold that may couple with a base of the remote plasma unit 660 and split flow from a single gas input of the remote plasma unit 660 to separate outlets to each of the output manifolds 635. Each separate gas outlet of the central manifold may be coupled with a side manifold 675 that defines at least a portion of a dedicated flow path to one of the output manifolds 635. In some embodiments, an isolation valve 690 may be positioned between each of the side manifolds 675 and output manifolds 635. The isolation valves 690 may provide fluid control to each processing chamber, as well as prevent backstreaming of gases to the remote plasma unit 660 and to prevent cross-talk between the various processing chambers.

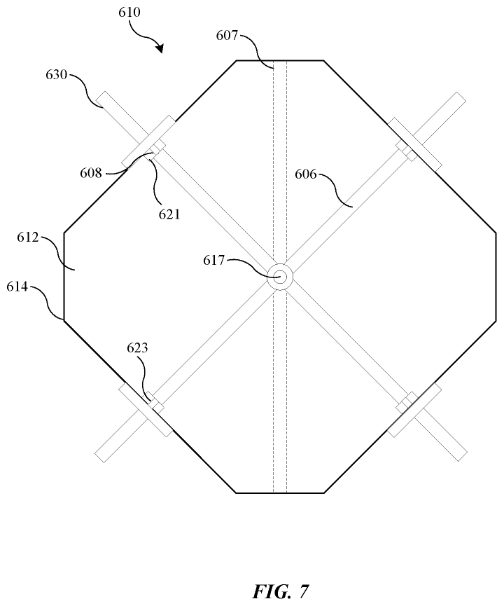

FIG. 7 shows a schematic cross-sectional top plan view of the gas splitter 610. Gas splitter 610 may include a body having a top surface 612 and a number of side surfaces 614. In some embodiments, the gas splitter 610 may be a monolithic structure, with any lumens and/or other apertures machined into the structure. Such a design may eliminate the need for ebeam welding and/or other joining techniques that may present opportunities for gas leakage and/or uniformity issues. As illustrated, the gas splitter 610 is octagonal in shape and has eight side surfaces 614, however other numbers of side surfaces 614 may be utilized in various embodiments to meet the needs of a particular application. As just one example, a number of side surfaces may be reduced for systems with fewer than four processing chambers and may be increased for systems with more than four processing chambers. Gas splitter 610 may include a gas inlet 617 that may be interfaced with an outlet end of the primary gas weldment 615 (as best shown in FIG. 6), which may enable a mixture of one or more gases to be flowed from a gas source through the primary gas weldment 615 and into the gas splitter 610. In some embodiments, the gas inlet 617 may extend through the top surface 612, while in other embodiments the gas inlet 617 may extend through one of the side surfaces 614 of the gas splitter 610. By positioning the gas inlet 617 through the top surface 612 of the gas splitter 610, a symmetrical flow path may be provided from the gas inlet 617 to each of a number of gas lumens 606 defined within the gas splitter 610, which may help distribute flow of the gas mixture equally to each of the processing chambers. In some embodiments, the primary gas weldment 615 may have a single outlet, which may further improve flow uniformity through the primary gas weldment 615 (and subsequently system 600) as a single flow path may be more easily machined or otherwise formed to tight tolerances. However, some embodiments may utilize a primary gas weldment that splits into multiple outlets.

As noted above, the gas splitter 610 may define a number of gas lumens 606 that extend between and fluidly couple the gas inlet 617 of the gas splitter 610 with a number of gas outlets 608 of the gas splitter 610. At least some of the gas lumens 606 may split gas flow from a single gas inlet to multiple gas outlets 608 such that the gas splitter 610 includes a greater number of gas outlets 608 than gas inlets. As illustrated, four gas lumens 606 are fluidly coupled with the gas inlet 617 and extend radially outward from the center of the gas splitter 610 to split flow from the primary gas weldment 615 to deliver gas to four (or other number based on a number of processing chambers included in system 600) different gas outlets 608. The gas lumens 606 may extend from the gas inlet 617 at regular and/or irregular angles. For example, as illustrated, each gas lumen 606 is positioned at a regular interval such that the angle between each gas lumen 606 and the gas inlet 617 is equal, which may help maintain flow directed to each gas lumen 606 (and subsequently each processing chamber) at substantially equal levels. A number of gas outlets 608 and/or gas lumens 606 may match a number of processing chambers of the processing system 600 in some embodiments. In some embodiments, each of the gas outlets 608 may extend through a respective side surface 614 of the gas splitter 610. Each of the gas outlets 608 may be positioned on a different side/area of the gas splitter 610. The split arrangement of gas lumens 606 may enable a single gas source to provide equal flow rates of gas through each of the four gas outlets 608 using a single primary gas weldment 615 (with a single outlet) and single gas splitter 610.

In some embodiments, the gas splitter 610 may include a heat source. For example, a heater cartridge 607 may be coupled with and/or embedded within a body of the gas splitter 610. In some embodiments, the heat cartridge 607 may be positioned at a center of the gas splitter 610, which may provide a uniform temperature gradient across the gas splitter 610. By providing a heat source within the gas splitter 610, greater temperature control may be afforded to the system 600, which may improve the quality and uniformity of film deposition operations. The heat source may heat the gas splitter 610 and/or maintain the heat of process gases at temperatures of about or greater than 75° C., about or greater than 100° C., about or greater than 125° C., about or greater than 150° C., about or greater than 175° C., about or greater than 200° C., or more.

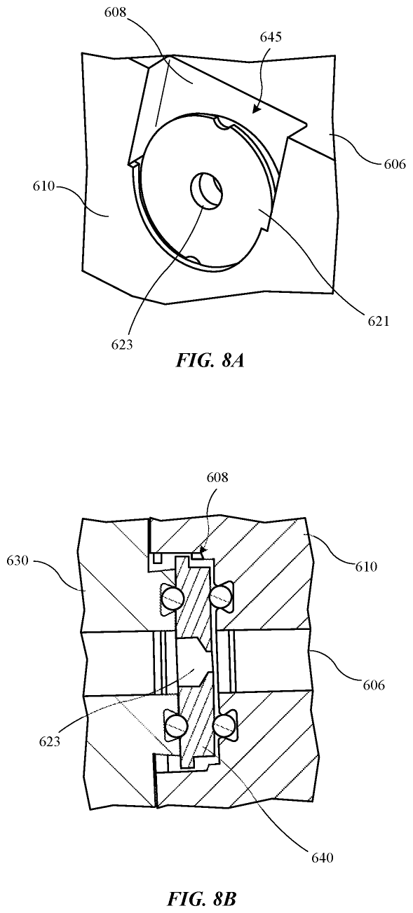

Gases exiting the gas outlets 608 of gas splitter 610 may pass into inlet ends of secondary weldments 630 for delivery to a respective output manifold 635. For example, an inlet end of each of the secondary weldments 630 may be coupled with a respective side surface 614 of the gas splitter 610 to fluidly couple the secondary weldment 630 with one of the gas outlets 608. Gas splitter 610 may also include one or more passive flow control devices that may be used to tune the flow rate to each of the processing chambers. For example, the gas splitter 610 may include a number of choke plates 621. In addition to enabling flow rates to be tuned for each chamber, the choke plates 621 may serve as a passive flow control device that enables downstream components (including output weldments, manifolds, lid stacks, etc.) to be modified or replaced without the need for any further flow rate tuning. Each choke plate 621 may be positioned at an interface of one of the secondary weldments 630 and a respective one of the gas outlets 608 of the gas splitter 610. For example, an opening of each gas outlet 608 of the gas splitter 610 may include a choke plate 621. As illustrated, each gas outlet 608 may define and/or otherwise include a slot that enables choke plates 621 to be inserted removed from the interface between the gas outlet 608 and the secondary weldments 630. FIG. 8A shows a schematic isometric view of one embodiment of a choke plate 621 secured with a gas outlet 608 of gas splitter 610 (although some embodiments may alternatively or additionally include a choke plate at an inlet end of the secondary weldment 630). The choke plate 621 may be received and secured within a slot formed at the gas outlet 608. In some embodiments, one or more O-rings may be used to seal the interface to prevent any gases flowing through the choke plate 621 from leaking out of the interface as illustrated in the schematic cross-sectional top elevation view of FIG. 8B. Each choke plate 621 may define a central orifice 623 that is used to choke the flow of gases to each processing chamber. For example, the central orifice 623 of each choke plate 621 may have a reduced aperture size relative to the gas lumens 606 and the secondary weldments 630. As illustrated, an upstream side of the central orifice 623 may have a smaller diameter than a downstream side of the central orifice 623. For example, a diameter of the central orifice 623 may taper and/or abruptly increase in diameter from the upstream side of the choke plate 621 to the downstream side. In other embodiments, the central orifice 623 may have a constant diameter across a thickness of the choke plate 621. The reduced diameter of the central orifice 623 relative to the diameters of gas lumens 606/gas outlets 608 and the secondary weldments 630 enables the central orifice 623 to serve as a passive flow control device that enables downstream components (including output weldments, manifolds, lid stacks, etc.) to be modified or replaced without the need for any further flow rate tuning. Each of central orifices 623 may have an internal diameter of between about 1.70 mm and about 2.40 mm, such as between about 1.80 mm and about 2.30 mm, between about 1.80 mm and about 2.10 mm, or between about 2.00 mm and about 2.30 mm. The diameters of the central orifices 623 may be the same or different across each of the choke plates 621. For example, if there is a flow rate and/or deposition rate mismatch in one or more of the chambers, the choke plate 621 associated with one or more of the chambers may be replaced with a choke plate 621 having a central orifice 623 of a different diameter. The difference in diameter may help correct any such mismatches to deliver more uniform flow rates and/or deposition rates across each of the processing chambers. In some embodiments, the system 600 may include a number of different choke plates 621 with different diameters of central orifices 623. For example, a number of different choke plates 621 having diameters spaced apart by one or more intervals may be provided that enable a flow rate to each of the chambers to be carefully tuned with a desired precision. The interval of diameters for the various central orifices 623 may be between or about 0.005 mm and 0.1 mm, between or about 0.00725 mm and 0.075 mm, between or about 0.01 mm and 0.05 mm, or between or about 0.02 mm and 0.04 mm, with smaller intervals providing greater tuning precision. The number and intervals of the central orifices 623 of the choke plates 621 provided with system 600 may depend on a flow rate and/or deposition rate mismatch tuning range and/or a desired uniformity precision.

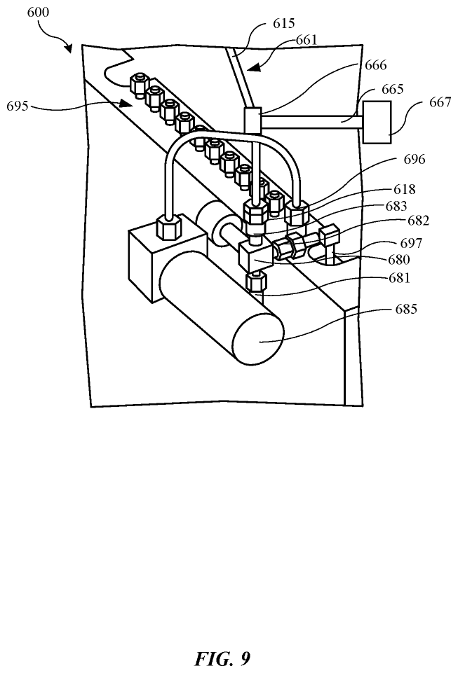

As noted above, the primary gas weldment 615 may be coupled with a gas source, such as a gas panel 695. FIG. 9 shows a partial schematic isometric view of gas panel 695 and related components of the semiconductor processing system 600 according to some embodiments of the present technology. The primary gas weldment 615 may include a primary gas weldment inlet 618. The primary gas weldment 615 may extend to and fluidly couple with at least one gas mixing valve 680, such as the primary gas weldment inlet 618. The at least one gas mixing valve 680 may have a first valve inlet 681, a second valve inlet 682, and a valve outlet 683. The at least one gas mixing valve 680 may control the flow (on/off, flow rate, etc.) of respective gases being flowed to the primary gas weldment 615 and may be used to mix multiple gases prior to delivering the process gases to the gas splitter 610. The valve outlet 683 may be in fluid communication with the primary gas weldment inlet 618 of the primary gas weldment 615. It is contemplated that more than two valve inlets, flowing more than two process gases, may be in fluid communication with the primary gas weldment inlet 618 of the primary gas weldment 615 via the at least one gas mixing valve 680. That is, multiple gas mixing valves may combine more than two processes gases.

As previously discussed, the processing system 600 may include the gas panel 695. The gas panel 695 may include a first gas source 696 and a second gas source 697. The first gas source 696 may be fluidly coupled with the first valve inlet 681, such as by one or more weldments. An outlet of the first gas source 691 may be fluidly coupled with the primary gas weldment 615, either directly or indirectly via one or more weldments having an outlet in fluid communication with the primary gas weldment 615. The second gas source 697 may be fluidly coupled with the second valve inlet 682, such as by one or more weldments. For example, an outlet of the second gas source 697 may be fluidly coupled with the primary gas weldment 615. One or more gas heaters 685 may be disposed upstream of one or more of the gas mixing valves. Each gas heater 685 may include an inlet and an outlet. The inlet may be coupled with outlets of one or more of the gas sources, while the outlet of the gas heater 685 may be coupled with one of the valve inlets. This may enable one or more gases to be flowed through the gas heater 685, which may then heat the gases to a desired temperature for a given processing operation. As illustrated, an inlet of the gas heater 685 may be coupled with an outlet of the first gas source 696 and the outlet of the gas heater 685 is coupled with the first valve inlet 681. The gas heater 685 may heat a first gas delivered from the first gas source 696 prior to delivering the first gas to the first valve inlet 681. The first gas and a second gas (supplied by the second gas source 697) may mix within the mixing valve 680 and may be flowed into the primary gas weldment 615 (via the valve outlet 683) for delivery to the gas splitter 610 and processing chambers. In a particular embodiment, the first gas may be an oxygen-containing precursors, and/or nitrogen-containing precursors while the second gas may be an silicon-containing precursors, although other combinations of gases are possible in various embodiments. Silicon-containing precursors may be or include, but are not limited to, tetraethyl orthosilicate (“TEOS”), silane, disilane, or other silicon-containing materials. Oxygen-containing precursors may be or include, for example, diatomic oxygen, ozone, or other oxygen-containing materials. Nitrogen-containing precursors may incorporate oxygen, water, alcohol, or other materials. For example, in one embodiment the first gas may be O₂, which may be heated prior to being mixed with TEOS (the second gas) and delivered to the gas splitter 610 for distribution to the various processing chambers.

As previously discussed, the various weldments may be surrounded by heater jackets, such as heater jackets 661. In embodiments, the primary gas weldment 615 may be surrounded by between one and six heater jackets, such as between one and five heater jackets, between one and four heater jackets, between one and three heater jackets, or between one and two heater jackets. For example, the primary gas weldment 615 and/or other components (including the secondary weldments 630) may each include one or more dedicated heater jackets 661. This may enable any number of heater jackets 661 to be used to match the contours of the jacketed component, which may simplify manufacture, installation, and/or servicing of the heater jackets 661 and/or jacketed components. Each of the heater jackets 661 may insulate all or a portion of a respective region of the gas delivery architecture to maintain the process gases at a desired temperature. For example, the process gases may be heated proximate the gas panel 695 (such as via gas heater 685) and/or in the gas splitter 610 (using heater cartridge 607). The heater jackets 661 may help maintain the temperature of the heated process gases, which may help reduce the power consumption of the processing system 600. Due to the architecture of the present embodiments, fewer heating jackets than conventional technologies may be necessary.

The processing system 600 may include a divert weldment 665 proximate the gas panel 695. The divert weldment 665 may be may be used to divert process gases away from processing chambers and into exhaust systems. Process gases may be diverted away from processing chambers for any number of reasons. For example, a portion of process gases may be diverted from one or more of the processing chambers to tune a flow rate of the process gases to the various chambers, such as to equalize flow to each chamber. In other instances, the process gases may be diverted away from each of the processing chambers while the gas panel or other gas source ramps up a flow rate of the process gases to a full flow rate. This diverting of process gases may be performed to ensure that only the full flow rate is delivered to the chambers, which may help improve the control of deposition rate within each of the processing chambers. As illustrated, the divert weldment 665 may be coupled to the primary input weldment 615 downstream and/or downstream of the at least one mixing valve 680. A divert valve 666 may be positioned on and/or otherwise fluidly coupled with the primary gas weldment 615. The divert valve 666 may include a valve inlet that may be fluidly coupled with the gas panel 695. The divert valve 666 may have a first divert valve outlet and a second divert valve outlet. The first divert valve outlet may be in fluid communication with the primary input weldment 615. The second divert valve outlet may be in fluid communication with a foreline 667 and/or the gas panel. Depending on whether process gases need to be diverted, the divert valve 666 may open and send a portion or all of the process gases to the divert weldment 665. The divert valve 666 may be closed and/or otherwise actuated to permit gases to flow through the first divert valve outlet to the primary input weldment 615. The divert weldment 665 may be in fluid communication with foreline 667. The foreline 667 may pump out and/or otherwise exhaust gases and particulate when the process gases are diverted away from the processing chambers.

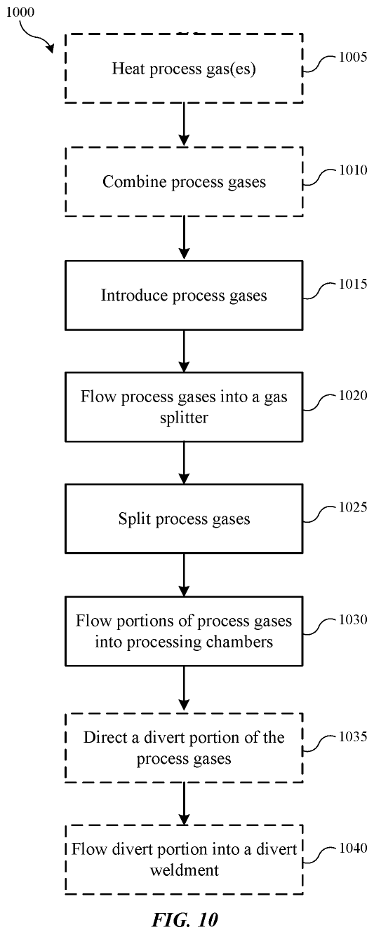

FIG. 10 shows operations of an exemplary semiconductor processing method 1000 according to some embodiments of the present technology. The method may be performed using a variety of processing systems, including processing systems 100 and 600. The processing systems may include any of the components, characteristics, or configurations described above. Method 1000 may include a number of optional operations, which may or may not be specifically associated with some embodiments of methods according to the present technology.

Method 1000 may be performed to heat, mix, and distribute process gases to processing chambers to achieve uniform flow rates and/or deposition rates across the various chambers. At optional step 1005, the method 1000 may include combining at least a first process gas and a second process gas to form a mixture of process gases. As previously described the process gases may include silicon-containing precursors, oxygen-containing precursors, and/or nitrogen-containing precursors. However, it is contemplated that any combination of process gases may be combined. In one embodiments, a first process gas may be TEOS and a second process gas may be diatomic oxygen. Other process gases or combinations of process gases may be used depending on the desired process to be performed in the processing system, as will be appreciated by one skilled in the art.

At step 1010, the method 1000 may include heating at least one of the at least two process gases prior to introducing the mixture of process gases into the primary gas weldment. For example, the at least one gas may be passed through a gas heater to heat the gas. It is contemplated that the mixture of process gases may be heated, but that, in some embodiments, it may be desirable to only heat less than all process gases in the mixture of process gases. For example, the second gas may be heated, while the first gas is unheated (until the gases are combined to form the mixture). In other words, the heating operation may be performed before and/or after combining the gases. The particular heating arrangement may be selected based on the properties or characteristics of the process gases being delivered to the processing chambers. For example, if some individual process gases and/or mixtures of process gases are heated, properties of the gases and/or mixtures may change. Additionally, for high flow recipes, the heater jackets alone may be insufficient to heat the gases to a desired temperature, necessitating the use of the heater proximate the gas panel. In embodiments where the process gases include TEOS and diatomic oxygen, the oxygen may be heated while the TEOS may not be heated.

At step 1015, the method 1000 may include introducing a mixture of process gases into a primary gas weldment. The mixture may include at least two process gases. As previously discussed there may be multiple input weldments to the gas splitter. However, in embodiments, a single gas splitter, such as the primary gas weldment, may deliver a mixture of all necessary process gases. Furthermore, the primary gas weldment may have multiple outlets coupled with the gas splitter, but each outlet may pass a same or similar mixture of process gases to the gas splitter. At step 1020, the method 1000 may include flowing the mixture of process gases into a gas splitter via a gas inlet. At step 1025, the method 1000 may include splitting a flow of the mixture of process gases into a plurality of gas lumens defined by the gas splitter. At step 1030, the method 1000 may include flowing portions of the mixture of process gases into respective processing chambers via a plurality of secondary gas weldments coupled with gas outlet ends of each of the plurality of gas lumens. In embodiments, one portion of the mixed process gas may be delivered to each respective processing chamber.

At optional step 1035, the method 1000 may include directing a divert portion of the mixture of process gas into a foreline. The gas may be diverted using one or more weldments and/or valves within or proximate the gas panel and/or other gas source(s). At optional step 1240, the method 1200 may include flowing the divert portion of the mixture of process gases through the divert weldment and into a foreline and/or other destination. Each of the processing stations may share a common divert weldment that flows the divert portion of the mixture of process gases away from the processing system. The diverting of gas may occur prior to the heating, mixing, and/or flowing the gases (e.g., prior to steps 1005, 1010, and/or 1015). For example, one or more of the gases may be diverted until gas source ramps up a flow rate of the process gases to a full flow rate, to tune a flow rate of the process gases to the various chambers, and/or achieve another purpose.

By using a single process feed weldment to the gas splitter, a more uniform flow may be delivered to each processing chamber. Further, by using a single process weldment, a plurality of individual valves associated with split portions of the feed are not needed at outlets of the gas splitter. A single valve controlling the flow of process gases may reduce the potential for pressure spikes and/or timing mismatches associated with a plurality of valves. With a more uniform flow, along with tuning of orifice sizes, deposition rates may be more uniform between the multiple processing chambers. Moreover, the use of a single valve lowers the electrical power requirement associated with the system. Finally, heating upstream of an inlet to the single process feed weldment may allow for better control of the heating and, again, for a lower electrical power requirement.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a lid” includes a plurality of such lid plates, and reference to “the gas splitter” includes reference to one or more gas splitters and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a plurality of processing chambers, each processing chamber defining a processing region;
a lid plate positioned above the plurality of processing chambers;
a gas splitter seated on the lid plate, the gas splitter comprising a top surface and a plurality of side surfaces, wherein the gas splitter defines:
a single gas inlet;
one or more gas outlets; and
one or more gas lumens that extend between and fluidly couple the single gas inlet with each of the one or more gas outlets;
a primary gas weldment that extends to and fluidly couples to the single gas inlet, wherein the primary gas weldment delivers a mixture of process gases to the plurality of processing chambers;
at least one gas mixing valve having a first valve inlet, a second valve inlet, and a valve outlet, wherein the valve outlet is coupled with an inlet end of the primary gas weldment; and
one or more secondary gas weldments extending between and fluidly coupling each of the one or more gas outlets with a respective one of the plurality of processing chambers.

2. The semiconductor processing system of claim 1, further comprising:
a gas panel comprising a first gas source fluidly coupled with the first valve inlet and a second gas source fluidly coupled with the second valve inlet.

3. The semiconductor processing system of claim 1, further comprising:
a gas heater disposed upstream of the at least one mixing valve, wherein the gas heater is operable to preheat at least one of the mixture of process gases.

4. The semiconductor processing system of claim 1, further comprising: a divert weldment in fluid communication with the primary gas weldment proximate a gas panel.

5. The semiconductor processing system of claim 1, further comprising:
one or more orifices disposed between the one or more gas outlets and the plurality of processing chambers, wherein the one or more orifices comprise an internal diameter less than an internal diameter relative to fluid lines disposed upstream and downstream of each of the one or more orifices.

6. The semiconductor processing system of claim 1, further comprising:
between one and six heater jackets surrounding the primary gas weldment.

7. The semiconductor processing system of claim 1, further comprising:
a plurality of output manifolds seated on the lid plate, wherein each of the one or more secondary gas weldments are fluidly coupled with a respective one of the plurality of output manifolds.

8. A semiconductor processing system, comprising:
a lid plate;
a gas splitter seated on the lid plate, the gas splitter comprising a top surface and a plurality of side surfaces, wherein the gas splitter defines:
a gas inlet;
one or more gas outlets; and
one or more gas lumens that extend between and fluidly couple the gas inlet with each of the one or more gas outlets;
a primary gas weldment that extends to and fluidly couples to the gas inlet, wherein the primary gas weldment delivers a mixture of process gases to a plurality of processing chambers;
a gas panel comprising a first fluid source and a second fluid source that are each fluidly coupled with the primary gas weldment; and
one or more secondary gas weldments extending between and fluidly coupling each of the one or more gas outlets with a respective one of the plurality of processing chambers.

9. The semiconductor processing system of claim 8, further comprising:
a gas heater in fluid communication with the primary gas weldment, wherein the gas heater is operable to preheat at least one of the mixture of process gases.

10. The semiconductor processing system of claim 8, further comprising:
a divert weldment in fluid communication with the primary gas weldment proximate the gas panel.

11. The semiconductor processing system of claim 10, further comprising:
one or more orifices between the one or more gas outlets and the plurality of processing chambers, wherein the one or more orifices comprise an internal diameter less than an internal diameter relative to fluid lines disposed upstream and downstream of each of the one or more orifices.

12. The semiconductor processing system of claim 11, wherein:
the one or more orifices are removable such that inner diameters of the one or more orifices may be modified.

13. The semiconductor processing system of claim 12, wherein:
each of the one or more orifices comprise an internal diameter of between about 1.70 mm and about 2.40 mm.

14. The semiconductor processing system of claim 8, further comprising:
between one and six heater jackets surrounding the primary gas weldment.

15. The semiconductor processing system of claim 8, further comprising:
at least one gas mixing valve having a first valve inlet, a second valve inlet, and a valve outlet, wherein:
the first valve inlet is in fluid communication with a gas heater, the gas heater operable to heat gas prior to being passed to the first valve inlet; and
the valve outlet is coupled with an inlet end of the primary gas weldment.

16. A semiconductor processing method comprising:
introducing a mixture of process gases into a primary gas weldment, wherein the mixture of process gases comprises at least two process gases;
flowing the mixture of process gases into a gas splitter via a gas inlet;
splitting a flow of the mixture of process gases into a plurality of gas lumens defined by the gas splitter; and
flowing portions of the mixture of process gases into respective processing chambers via a plurality of secondary gas weldments coupled with gas outlet ends of each of the plurality of gas lumens.

17. The semiconductor processing method of claim 16, further comprising:
heating at least one of the mixture of process gases prior to introducing the mixture of process gases into the primary gas weldment.

18. The semiconductor processing method of claim 16, further comprising:
directing a divert portion of the mixture of process gases into a divert weldment; and
flowing the divert portion of the mixture of process gases through the divert weldment and into a divert foreline.

19. The semiconductor processing method of claim 16, further comprising:
combining at least a first process gas and a second process gas to form the mixture of process gases.

20. The semiconductor processing method of claim 19, wherein:
the first process gas comprises O₂ and the second process gas comprises TEOS; and
the method comprises heating the O₂ prior to combining the O₂ and the TEOS.
